(19) United States
(12) Patent Application Publication
(10) Pub. No.: US 2005/0199185 A1
(43) Pub. Date: Sep. 15, 2005

(54) Convertible maintenance valve

(76) Inventors: Holger Richert, Bruckkobel (DE); Andreas Sauer, Grossostheim (DE); Guido Hatten dorf, Brachttal (DE)

Correspondence Address: PRICE HENEVELD COOPER DEWITT & LITTON, LLP, 695 KENMOOR, S.E., P O BOX 2567, GRAND RAPIDS, MI, 49501, US

(21) Appl. No.: 11/080,082

(22) Filed: Mar. 15, 2005

(30) Foreign Application Priority Data
Mar. 15, 2004 (EP) 04 006 113.7

(51) Int. Cl. F04B 27/08; C23C 16/00

(52) U.S. Cl. 118/715

(57) ABSTRACT

A vacuum treatment unit, especially for continuous coating of passing substrates, preferably a glass coating unit, with at least two, preferably various adjacently disposed chambers or chamber areas which by means of one or various chambers and/or separating walls are reciprocally separated and are interconnected through openings in said chamber and/or separating walls, preferably slotted locks for the passage of said substrates, and at least one opening may be closed in vacuum-tight fashion by means of a valve unit for vacuum-tight separation of chambers and/or chamber areas, and a valve unit is separably attached inside the chamber, especially on the inside of the chamber and/or separating wall.

### CROSS-REFERENCE TO RELATED APPLICATION

This application claims priority to European Patent Application No. 04 006 113.7 filed on Mar. 15, 2004, entitled CONVERTIBLE MAINTENANCE VALVE.

### FIELD OF THE INVENTION

The present invention refers to a vacuum processing plant.

### BACKGROUND OF THE INVENTION

Vacuum processing plants, especially glass coating plants in the present case, in which the glass substrates to be coated are being continuously conducted through a variety of adjacently disposed chambers or chamber areas (compartments), where they are subject to different processes, are widely used.

In order to avoid reciprocal interference amongst the processes accomplished in the different chamber areas (compartments), said compartments or areas are usually reciprocally separated in vacuum-tight fashion with different compartments and being pumped out separately, and only so-called slotted locks are integrated between the compartments, i.e. chambers, in order to be able to move said substrates to be coated from one compartment into another. With these slotted locks, which are essentially built in the form of a slot-like opening between said compartments, i.e. chambers, it becomes possible, on one side, to continuously move said glass substrates, in the form of panes, on corresponding conveyor units, such as, for example, roller conveyors, without any additional activation of valves or locks, and, on the other side, an undesired exchange of atmosphere between adjacent compartments is avoided.

Nevertheless, usually between certain compartments or chambers, additional separating valves are being integrated, which render possible a total gas-tight or vacuum-tight separation of said compartments or chambers, in order that at the occasion of maintenance activities or exchange of feeder cathodes, the entire coating unit does not have to be aerated, but only the section affected with maintenance or exchange work.

Based on the required vacuum-tight disposition of said separating valves contained in said compartments, and the required adjustment with process or measuring tools, the space and disposition of separating valves is predetermined and fixed during the construction of a glass coating unit, so that it is precisely defined which areas may sequentially be reciprocally locked through the separating valves.

### SUMMARY OF THE INVENTION

An aspect of the present invention comprises providing a vacuum coating unit, and especially a continuously operating glass coating unit, which renders possible an effective and varied utilization of said glass coating unit, as well as its production.

The inventors recognized that glass coating units, where separating valves are firmly and fixedly integrated during the construction of said glass coating unit, present considerable disadvantages concerning a variable and effective utilization, as during a change of the coating processes, for example, as a result of a modification in the layer sequence, possibly a varied occupation of compartments with variable coating or process tools has to take place and, consequently, the predetermined disposition of said separating valves is no longer adequate for the maintenance tasks that are adequate vis-à-vis the changed coating process.

In accordance with an aspect of the invention, this problem may be solved due to the fact that said separating valves are being separately attached inside the different chambers or chamber areas, so that, in case of need, said separating valves may, at any time, be displaced or changed in their disposition, in order to create other separable areas in the glass coating unit or vacuum treatment unit.

It is especially not required to integrate said separating valves, i.e. valve units, into separate housings between adjacent chambers, which additionally requires considerable space, but the valve units are preferably being attached on the inside of said chambers and/or separating walls, so that a distanced disposition of adjacent chambers, due to integration of intermediate separating valves, is being effectively avoided.

Advantageously, both the valve unit as well as the chambers are built in such a fashion that without undergoing essential changes on the chamber and/or separating walls, where they are attached, the valve unit may be mounted in said sections or from which they may again be removed.

It is also advantageous when said valve unit, on one side, and the chamber with the process tools and transportation units for the substrates therein integrated, on the other side, are in such fashion reciprocally synchronized that said valve unit may be mounted independently from process tools and transportation units inside the chamber, i.e., at the chamber or separating walls. This will be especially attained when the separating valve, i.e., said valve unit, features especially small dimensions and is built in a special plane fashion, so as to avoid collisions with process tools and/or transportation units.

Due to the moveably attached disposition of the valve unit (separating valve) inside the chamber, assembly or removal of a separating valve can thus essentially result in no change in the chamber or in the disposition of the process tools and the transportation unit inside the chamber, at least after assembly or removal, as well as in a change in the reciprocal position of chambers, which normally cannot be accomplished altogether. Also, the additional integration of individual separating valve housings between said chambers is thus being eliminated.

Preferably, said valve unit features a housing, with which the valve unit may be integrated in a vacuum (e.g., gas-tight fashion) inside the chamber (e.g., at the chamber or compartment wall). Vacuum-tight means, in this case, that especially in a radial direction, starting from the passage opening for said substrates, seals are provided at the connections, in order to insure—with closed valve lid—a vacuum-tight (i.e., gas-tight) separation of the compartment (i.e., of the chamber area), thus insuring tightness of the separating or chamber wall also alongside the valve housing.

Preferably, said valve unit, (i.e., separating valve) with its housing is disposed through a mounting support in the area of said slotted locks at the chamber (at the separating walls) with said mounting support, preferably in the form of a clamp, embracing said adjacent chamber wall or separating wall around the passage opening. This insures an especially simple attachment without extensive changes at the chambers or compartments.

Preferably, said mounting support and separating chamber walls feature complementary intermeshing steps, in order to create an especially tight connection at this point.

Preferably, said separating valve, which may be a slide or flap valve, may also feature a valve flap with rotative or translatory movement during the closing step, and may also be built as a slide valve, which may close said opening in both directions, so that the valve unit may be mounted on one or on the other side under vacuum or atmospheric conditions. In corresponding fashion, seen in the transport direction, the valve unit variably may also be mounted in front or behind a chamber or separating wall.

Further details and advantages of the object of the present invention are depicted in the drawings of an example of execution and based on the subsequent description.

### BRIEF DESCRIPTION OF THE DRAWINGS

FIG. 1 shows, schematically, a longitudinal cut through a glass coating unit with different chambers and chamber areas (compartments).

FIG. 2 shows, schematically, a cross section of the slide valve according to the invention, in the operating position of the slide plate.

FIG. 3 shows a comparable cross section in the inactive position of the slide plate.

### DETAILED DESCRIPTION OF THE PREFERRED EMBODIMENT

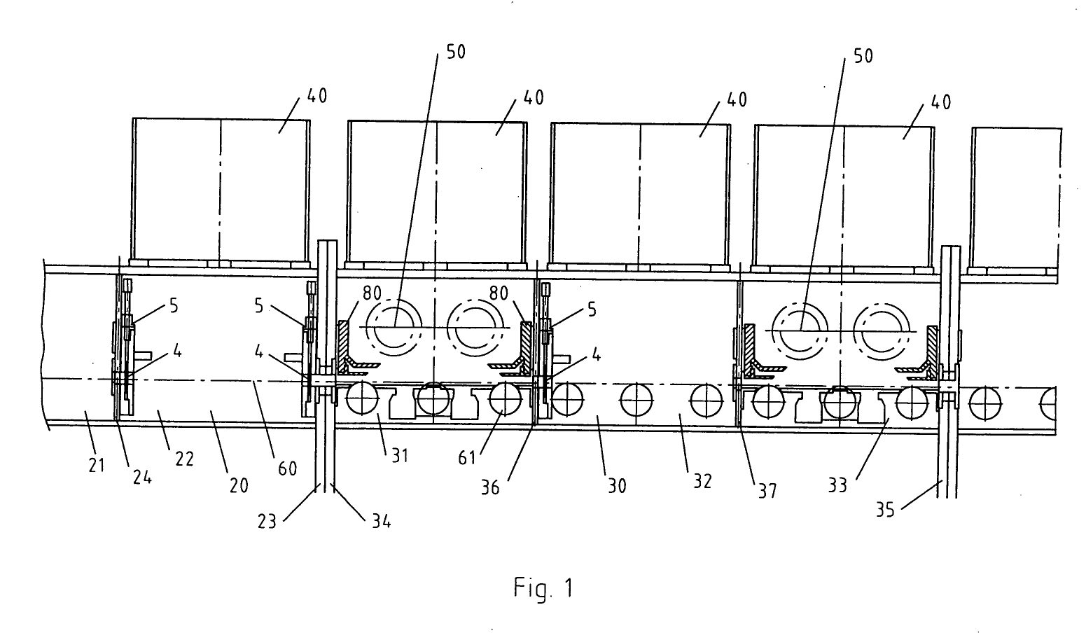

FIG. 1 shows, in cross section, part of a glass coating unit with two adjacent chambers 20, 30, which are subdivided into different compartments 21, 22, 31, 32 and 33.

The chamber 30 is limited by chamber walls 34 and 35, built as chamber flanges, whilst chamber 20, adjacent to chamber wall 34 of chamber 30, features a chamber wall 23 in the form of a chamber flange.

Compartments 21, 22, 31, 32 and 33 are reciprocally vacuum-tight separated inside chambers 20,30, by separating walls 24, 36 and 37, having said openings 4, acting as slotted locks for substrate passage.

At the chambers 20 and 30, upper sections pumping units 40 are provided, designed to pump off compartments 21, 22 and 31 to 33, in order to adjust vacuum conditions for the coating procedure.

Inside the compartments, whose compartment—i.e., chamber—construction is essentially identical, different processes or working steps may be accomplished, such as, for example, coating processes, measurements or similar actions, or they may be used as gas separating steps between compartments with different coating tools. Compartment 22, for example, is built as a measuring compartment and compartments 31 and 33 as coating compartments with pivotable dual magnetron cathodes 50, whilst compartment 32 is built, for example, as a pump compartment.

The substrate moves along dotted line 60 at a conveyor unit, preferably equipped with different conveyor rollers 61 through the different compartments, with transition from one compartment to another compartment, i.e., between chambers, taking place through openings 4, which are in the form of slotted locks.

Especially at compartments 31 and 33, built as coating compartments, a diaphragm device 80 may be integrated at separating walls 36, 37 and/or chamber walls 34, 35.

The different chamber areas (compartments) or chambers may be locked in a vacuum-tight fashion by means of the variable disposition of separating valves 5, in order to be able to aerate only partially said glass coating unit at the occasion of maintenance activities. For example, compartment 31 with separating valves 5 at separating wall 36, on one side, and chamber walls 23 and 34, on the other side, may be locked vacuum-tight, in order, for example, to exchange internal cathodes 50, without the need of aerating the remaining sections of the unit.

Since, according to the present invention, said separating valves 5 are separably attached at separating walls 24, 36, 37 or chamber walls 23, 34, 35, during a change in coating processes, which may eventually require another separation of the global unit for maintenance tasks, they may be removed from said separating or chamber walls, being attached at other separating or chamber walls. It is essential that separating valves 5 may be disposed on each chamber and/or separating wall, so that each selected component of the coating unit may selectively be closed in a vacuum-tight condition.

Based on the subsequently described disposition of a preferred separating valve 5, it is preferably also possible to integrate said separating valves in the transport direction of the substrate, in front of or behind said chamber or compartment wall, which additionally insures that the sealing direction is feasible in either or both sealing directions, so that one side, as well as on the other side of separating valve 5, atmospheric or vacuum conditions may prevail.

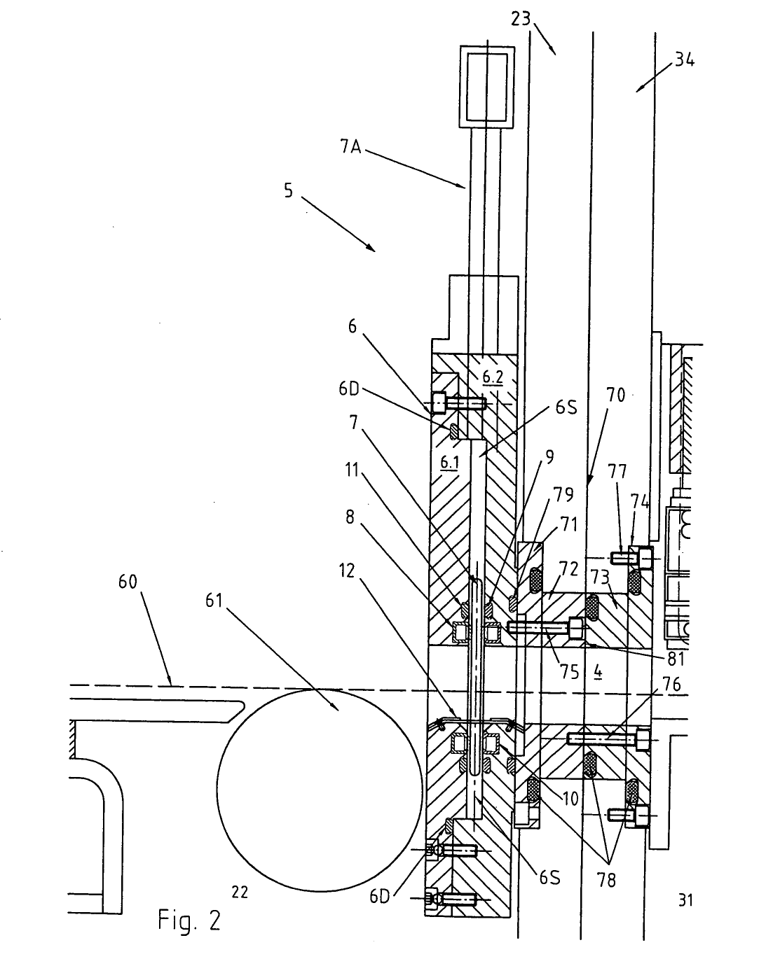

FIG. 2 shows, in an expanded scale, a cross section at the point of transition from compartment 22 to compartment 31 with the passage opening 4, which, vertically towards the plane of drawing, may clearly evidence larger dimensions than in its height now visible, i.e., it may be regarded in a slotted form, but, on the whole, it is built with the smallest possible free cross section. In the case of preferred use, it must exactly be sufficiently large to permit passage of smooth glass panels of over 3 m width.

Both chambers may be seen in the area of opening 4 which are quite tightly and firmly interconnected, in order to avoid any type of formation of a collateral current, when this opening 4 is closed with the slide valve, which will now be described, and when, for instance, inside compartment 31 a vacuum is present, whilst compartment 22 is in the process of being aerated.

Initially, said slide valve 5 encompasses housing 6 with two housing sections 6.1 and 6.2. It is understood that said housing 6 is specifically quite well sealed, being composed of different components. One may recognize here, for example, a sealing ring 6D in the slot between both housing sections 6.1 and 6.2, and another sealing ring 79 in the slot between housing section 6.2 and retaining wall 70, on which housing 6, as a whole, is attached in the area of opening 4.

Housing 6, as a whole, is equally transfixed by opening 4, i.e., it features a channel, forming an extension of said opening 4 with a free and continuous cross section.

One may recognize that, contrary to the initially indicated state of the art, the present slide valve does not necessarily have to be assembled between both compartments 22 and 31, but its housing 6 may be unilaterally disposed on the inner section of compartment 22.

Both housing sections 6.1 and 6.2 form amongst them a guide-slot 6S, in which a slide plate 7 is assembled with reduced lateral clearance in pendulous fashion, i.e., seen in the normal direction towards its main areas. It is suspended on a translatory actuator 7A, not indicated in detail. Its regulating component, not shown here in detail, is adequately linked with said slide plate 7, in order to render possible its lateral deflections. This connection between actuator 7A and said slide plate 7 transfixes housing 6.

The (vertical) guide-slot 6S, in the same way as said slide plate integrated therein, extends transversally towards (a horizontal) passage device of opening 4, in segments on both sides of the plane of transportation 60. Its essentially longitudinal section is located above said plane of transportation 60, but a small section is foreseen also underneath.

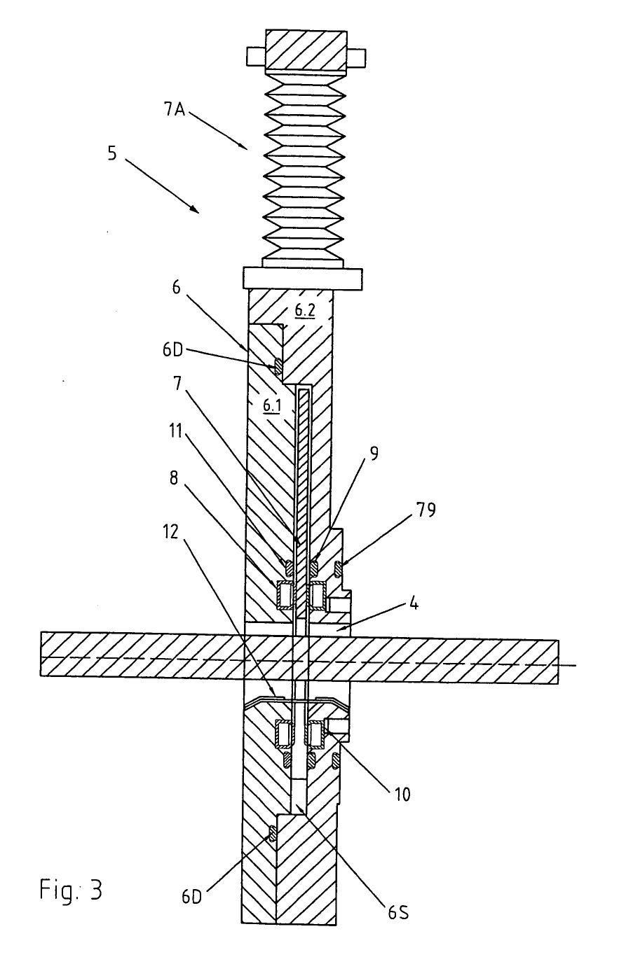

Inside guide-slot 6S, slide plate 7 may be reversibly activated by means of actuator 7A, between an inactive position (see FIG. 3), in which opening 4 is totally open and substrates may pass through, and the working or closed position shown in FIG. 2 in which slide plate 7 wholly covers slotted opening 4.

In the inactive position, slide plate 7 is wholly integrated into the upper section of guide-slot 6S. In the operating position, its lower edge penetrates in a bladelike fashion into the lower section of guide-slot 6S, whilst its upper portion still remains in its upper section. It is essential that slide plate 7 covers the entire border of opening 4.

The reversible movement of slide plate 7 by means of actuator 7a initially takes place freely, without a too tight guiding action in guide slot 6S (also with a negligible friction rate). Consequently, actuator 7A does not have to apply too intense regulating power. It may be, for example, a pneumatic or hydraulic lifting cylinder, a rack-and-pinion drive or an electromagnetic linear engine. It does not have to carry out a long stroke (a few centimeters) and must be able to place a sealing plate only relatively superficially in its working position.

Connection of the actuator with the slide plate requires, in any case, as already outlined, a certain degree of elasticity or articulateness, since slide plate 7, which will now be described, must be moveable also vertically towards the adjusting direction of linear drive 7A, even only for a few strokes. For this purpose, for example, at the end of the adjusting component of actuator 7A, a fork could be disposed, whose two flanks are interconnected by means of one, two or more axes, on which said slide plate 7 is moveably suspended in the required way.

It should be noted that actuator 7A represents various similar synchronously commanded actuators, which are to be used in case of need, when slide plate 7 is extended eventually over various meters length vertically towards the plane of drawing.

In the left half of housing 6.1, a first closing mechanism 8 is provided. It is preferably produced as an inflatable sealing, introduced into a circumferential annular slot of the housing wall, embracing, on its turn, the entire circumference of opening 4. Functionally corresponding with this closing drive 8, an annular sealing ring 9 is provided, which in the wall of the opposed half of housing 6.2 also is inserted into an annular slot, and which also totally embraces opening 4.

Exactly opposed (relative to the middle plane of guide slot 6S and slide plate 7) to said closing mechanism 8, in the example shown, in the opposed wall of housing section 6.2, a second closing mechanism 10, of the same format as closing mechanism 8, is inserted. It is located inside the area circumscribed by annular seal 9.

With the closing mechanism 10, an annular seal 11 functionally corresponds, which is inserted into the wall of housing section 6.1, again exactly in a direction opposite of annular seal 9, circumferentially involving closing mechanism 8.

It is actually contingent upon the embodiment, whether the closing mechanisms 8 and 10 are disposed inside or outside of the areas circumscribed by sealing rings 9 and 11. In the last case, the closing mechanisms are protected on the closed side against the influence of a vacuum. In the first case, the closing mechanism protects the sealing ring against overspray, located on the same side, to avoid undesired deposits of coating particles which, originated in the vacuum chamber, could reach the opening and the valve.

As already indicated, it is not forcibly required to produce the closing mechanisms 8 and/or 10 as uniform, circumferential chambers, similar to tube tires. Especially, it may also be considered to provide the closing mechanisms only as two parallel long and extended segments on both sides of opening 4, instead of providing them in a circumferential manner. This would also insure essential protection of the sealing rings against overspray.

In addition, a number of individual chambers could be uniformly distributed along the circumference of the sealing surfaces, which, evidently, would fluidly intercommunicate and would have to be synchronously exposed to pressure.

It is foreseen, in the context of the present invention, that only one of the closing drives may be foreseen, when the slide plate has to be prepared in a sealing position only in one direction.

The circumferential configuration of the closing drives 8 and 10 as herein explained, offers the advantage that with an adequate configuration of their outer sections, they are propped up as secondary seals on the smooth surface of slide plate 7, thus reinforcing the sealing action of sealing rings 9, 11, as long as their inner area is pressurized.

Below plane of transportation 60, in the area of opening 4 and of guide slot 6S, inside the housing a strip 12 of permanently elastic material is interchangeably attached. It closes the section of guide slot 6S, located below the plane of transportation, and avoids penetration of particles into the lower section of guide slot 6S. It is built divided as a lip seal and permits free penetration of slide plate 7, once it is moved into its operating position.

It is understood that seal rings 9 and 11, as well as closing drives 8 and 10, are introduced to such an extent into the respective housing walls, (they may eventually therein be introduced by means of exposure to subpressure) so that it is possible to exclude damages or only friction by contacts with the slide plate 7 during its reversing movements between the inactive and operating position.

Additionally, by means of adequate protective measures, the activation of the actuator 7A should, of course, be avoided when one of the closing drives 8 and 10 is pressurized. A merely manual activation of slide plate 7 in the activated condition of one of the closing drives 8 or 10 should nevertheless be impossible due to the intense compressing forces.

It can be seen that compared with the thickness of housing components 6.1 and 6.2, slide plate 7 may be produced in a quite slim and light fashion. In cooperation with a possibly uniform distribution of the closing forces, originated by closing drives 8, 10, slide plate 7 will be able to adjust itself exactly to the course of the sealing rings 9, 11, respectively, even when these should evidence small long-wave deviations from the ideal sealing plane.

In the case of regulation, slide plate 7 will be activated by actuator 7A when pressure in both modules to be reciprocally separated (still or again) is equal, for example (when on both sides atmospheric pressure or a vacuum is applied).

Once its operating position has been attained (its lower edge is submerged in the lower portion of guide slot 6S), then in accordance with the direction of the pressure differential (still to be formed) (e.g., vacuum in compartment 31, atmospheric pressure in module 22 or vice-versa) still to be neutralized, one of the closing drives 8 or 10 is fed/subject to internal pressure, when preferably the closing mechanism, not facing the lower pressure level, is being activated.

If, for example, in the closed position of slide valve 5, a vacuum should be applied in module 31, the (left) closing mechanism 8 will be activated. Due to the resulting inflation of its transversal tube section, slide plate 7 will be forced against (the right) annular seal 9.

If, on the other hand, in the closed position of slide valve 5, pressure in module 22 should become smaller than pressure in module 31, then the (right) closing drive 10 will be activated in order to moveably force slide plate 7 against the (left) annular seal 11.

With these measures, the load of the flexible convex surface of closing drives 8, 10, respectively, with excessive pressure differentials (internal pressure against vacuum) is being avoided.

Evidently, the compression force of closing drives 8, 10, respectively with growing formation of a pressure differential between compartments 22 and 31, is being additionally reinforced, since the more intense pressure on one side of slide plate 7 exerts a still stronger pressure on annular sealing 9, 11, respectively.

It is, furthermore, understood that closing drives 8 and 10 are the effective valve drives, which insure the sealing function. Actuator 7A is only foreseen for placing said slide plate in its overall operating position, independently of the direction of the pressure differential. Consequently, the effective sealing function of slide valve 5 and of the integral slide plate 7, can be used here in both directions, by optionally activating one of the closing drives 8 or 10.

It can be seen that the example of execution above described and shown of slide valve 5, featuring its components with sealing functions, is built in specular symmetry and, therefore, is apt to sustain a high pressure differential bidirectionally over the plane of slide plate 7. However, one may also imagine its embodiment for only one sealing direction, when either closing drive 8 and annular seal 10, or annular seal 9 and annular seal 11, may be eliminated.

After decline of the pressure differential to be purged by slide valve 5 and after active retraction of the formerly activated closing drive 8 or 10, actuator 7A may again move the slide plate towards its inactive position. Eventually, separating of slide plate 7 from annular seals 9 or 11 may be reinforced by flat or cup springs, not shown here, whose restoring force must be naturally overcome by the closing drives.

FIG. 2, in a cross-sectional view, also represents said retainer 70, with which said separating or slide valve 5 is disposed, with its housing 6 at the chamber walls 23 and 34 of said adjacent compartments 22 and 31.

Retainer 70 encompasses a first step plate 71,72, which, in the substrate passage direction, features two different areas 71 and 72 with different longitudinal and width dimensions, so that the first step plate 71,72 may be introduced into opening 4 and a steplike recess of chamber wall 23. During this procedure, a seal 78, circumferentially disposed around slot opening 4, will be propped up against chamber wall 23 in said step area, in order to obtain a radial sealing of the first step plate 71, 72 vis-à-vis chamber wall 23. As now shown, the first step plate 71, 72 may be built as an integral, or also divided, unit with separate areas 71 and 72.

Through a screwed connection 75, which may encompass various screws surrounding opening 4, the first step plate 71,72 is united with housing 6 of the slide valve 5. On a common stop face between the first step plate 71,72 and housing 6, especially housing section 6.2, a seal 79 is also shown, surrounding said opening, so that a radially vacuum-tight connection between housing 6 and the first step plate 71,72 is also provided.

Next to the first step plate 71, 72, a second step plate 73,74 is provided, which also features a steplike configuration being symmetrical relative to the first step plate 71,72, penetrating into a corresponding steplike recess of chamber wall 34. On the stop or sealing surface 81, on which first and second step plates establish mutual contact, a seal 78 is provided, also surrounding opening 4, so that also radially a vacuum-tight connection is provided between the first step plates 71, 72 and second step plates 73, 74. The second step plate 73, 74, which may also be built in two sections with areas 73 and 74, through a screwed connection, which also features preferably different screws 76 surrounding said opening, is connected to the first step plate 71, 72 and additionally through the screwed connection 77, which also may feature various screws surrounding said opening, being connected with chamber wall 34, so that through screwed connection 76, said retainer 70 in opening 4 embraces the marginal sections of chamber walls 23 and 34 in a clamp-like manner, in order to dispose, in this way, the retainer and the separating valve 5 vacuum-tight at chamber walls 23 and 34.

In the closed valve position, i.e., in the position of slide plate 7 of FIG. 2, in any way a gas-tight separation between compartments 22 and 31 may be established, and a sealing direction may be freely selected, so that on one side, as well as on the other side of separating valve 5, atmospheric or vacuum conditions may prevail.

With the plane configuration of separating valve 5, this valve may be disposed at the chamber walls 23 and 34, independently from transportation unit 60, 61, respectively (for example, a change of transportation unit is not required).

In addition, in case of need, by loosening screwed connections 77, 76 and eventually 75, said separating valve 5 may simply be removed and reinstalled. This enables a variable usage of separating valves in all areas of the unit.

The above description is considered that of the preferred embodiment only. Modification of the invention will occur to those skilled in the art and to those who make or use the invention. Therefore, it is understood that the embodiment shown in the drawings and described above is merely for illustrative purposes and not intended to limit the scope of the invention, which is defined by the following claims as interpreted according to the principles of patent law, including the doctrine of equivalents.

1. A vacuum treatment unit comprising:
at least two adjacently disposed chamber areas being separated by at least one wall, the at least one wall having an opening therein for passage of substrates, the chamber areas being interconnected such that the opening may be closed by a valve unit for vacuum-tight separation of the chamber areas;
wherein said valve unit is separably attached inside said chamber.

2. The vacuum treatment unit of claim 1, wherein:
the chambers are for continuous coating of passing substrates.

3. The vacuum treatment unit of claim 2, wherein:
the chambers are for coating glass.

4. The vacuum treatment unit of claim 1, wherein:
the at least one wall includes slotted locks for passage of substrates.

5. The vacuum treatment unit of claim 1, wherein:
said valve unit is separably attached on an inside of the at least one wall.

6. The vacuum treatment unit of claim 1, wherein:
the valve unit is attached in such a way to the at least one wall such that attaching and/or removal may be carried out without essentially altering the at least one wall.

7. The vacuum treatment unit of claim 1, wherein:
the valve unit is on a first side of the at least one wall;
the chamber areas include internally disposed process tools and substrate transportation units on a second side of the at least one wall; and
disposition or removal of the valve unit from the at least one wall may be accomplished without altering the chamber areas and/or altering disposition of the process tools and/or the transportation units inside the chamber areas.

8. The vacuum treatment unit of claim 1, wherein:
disposition or removal of the valve unit from the at least one wall may be accomplished in both activated and deactivated operating conditions of the unit.

9. The vacuum treatment unit of claim 1, wherein:
the valve unit comprises a housing and a valve lid mobile inside the housing for providing a vacuum-tight closing of the opening; and
when the valid lid is in a closed position, the housing is vacuum-tight and separably attached at the at least one wall.

10. The vacuum treatment unit of claim 1, wherein:
the valve unit is separably attached to the at least one wall at the opening by a retainer.

11. The vacuum treatment unit of claim 10, wherein:
the retainer comprises a clamp that embraces the at least one wall in a vacuum-tight fashion alongside a circumferential section of the opening.

12. The vacuum treatment unit of claim 10, wherein:
the valve unit is attached in a vacuum-tight fashion on the retainer.

13. The vacuum treatment unit of claim 12, wherein:
the valve unit is separably attached to the retainer.

14. The vacuum treatment unit of claim 10, wherein:
the retainer comprises a first and a second step plate in two sections, each provided with a central slot-like opening, the first and second step plates each having two areas of different length and/or width which compose a step;
the first step plate engaging the valve unit;
the second step plate engaging the at least one wall;
the step plates being separably interconnected;
stop faces are provided between the valve unit and the first step plate, between the second step plate and the wall, and between the step plates; and
seals are integrated in the first and second step plates.

15. The vacuum treatment unit of claim 14, wherein:
the at least one wall includes a steplike recess on an inside surface into which said step plates penetrate.

16. The vacuum treatment unit of claim 14, wherein:
the first and second step plates and the at least one wall are connected by screwed connections.

17. The vacuum treatment unit of claim 1, wherein:
the valve unit is a slide valve.

18. The vacuum treatment unit of claim 1, wherein:
the valve unit is a flip valve.

19. The vacuum treatment unit of claim 1, wherein:
the valve unit is adapted to close the opening in both sealing directions and, thus, independent of an atmospheric and vacuum side.

20. The vacuum treatment unit of claim 1, wherein:
the valve unit includes a housing in two sections;
the sections are radially vacuum-tight interconnected to the opening;
the two sections include a guide slot;
further including a moveable flap movable in the guide slot;
the moveable flap configured to be displaced between a first position which closes the opening and a second position which opens the opening;
the two sections including at least one actuator adjacent the guide slot, the at least one actuator being configured to be forced against at least one sealing face of the movable flap.

21. The vacuum treatment unit of claim 20, wherein:
the at least one actuator comprises two actuators.

22. The vacuum treatment unit of claim 21, wherein:
the two actuators comprise a first actuator and a second actuator, the first actuator being configured to be forced against a first sealing face of the movable flap and the second actuator being configured to be forced against a second sealing face of the movable flap.

23. The vacuum treatment unit of claim 22, wherein:
the valve unit includes a first seal configured to engage the second sealing face of the movable flap when the first actuator is forced against the first sealing face of the movable flap; and
the valve unit includes a second seal configured to engage the first sealing face of the movable flap when the second actuator is forced against the second sealing face of the movable flap.

24. The vacuum treatment unit of claim 20, wherein:
the at least one actuator is operated by fluid pressure.

25. The vacuum treatment unit of claim 20, wherein:
the at least one actuator comprises an elastically moveable element.
